(19) United States
(12) Patent Application Publication
(10) Pub. No.: US 2023/0352418 A1
(43) Pub. Date: Nov. 2, 2023

(54) SEMICONDUCTOR DIE, SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Yu-Hung Lin, Taichung City (TW); Po-Hsun Chang, Hsinchu County (TW); Yu-Kuang Liao, Hsinchu City (TW); Chia-Hui Lin, Taichung County (TW); Shih-Peng Tai, Hsinchu County (TW); Kuo-Chung Yee, Taoyuan City (TW)

(73) Assignee: Taiwan Semiconductor Manufacturing Company, Ltd., Hsinchu (TW)

(21) Appl. No.: 17/730,217

(22) Filed: Apr. 27, 2022

(51) Int. Cl. H01L 23/538; H01L 21/48; H01L 23/00

(52) U.S. Cl. CPC H01L 23/5389; H01L 23/5383; H01L 23/5386; H01L 21/4853; H01L 21/4857; H01L 24/03; H01L 24/05; H01L 24/08; H01L 24/20; H01L 24/80; H01L 2224/03614; H01L 2224/05018; H01L 2224/0508; H01L 2224/08145; H01L 2224/214; H01L 2224/80895; H01L 2224/80896

(57) ABSTRACT

A semiconductor die, a semiconductor package and manufacturing methods thereof are provided. The semiconductor die includes: a front-end-of-line (FEOL) structure, built on a semiconductor substrate; a back-end-of-line (BEOL) structure, formed on the FEOL structure, and including a stack of metallization layers; and bonding metals, disposed on the BEOL structure. The bonding metals include: a conductive pad, disposed over the BEOL structure, and electrically connected to the metallization layers in the BEOL structure; a conductive capping layer, lining along a top surface of the conductive pad; and an engaging feature, landing on the conductive capping layer and separated from the conductive pad by the conductive capping layer. The semiconductor die is bonded to another semiconductor die or a package component by the engaging feature.

### BACKGROUND

In recent years, semiconductor industry has strived to continually reduce feature size and power consumption of various electronic components, while on the other hand increasing device density, wire density and operation frequency of the electronic components. These advanced electronic components also require smaller packages that utilize less area than packages of the past.

Three dimensional integrated circuit (3DIC) is a recent development in semiconductor packaging in which multiple semiconductor dies are stacked upon one another. 3DIC provides improved integration density and other advantages, such as greater operation speed and higher bandwidth, because of the decreased length of interconnects between the stacked dies. However, there are quite a few challenges to be overcome for the technology of 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view illustrating a semiconductor die included in a semiconductor package, according to some embodiments of the present disclosure.

FIG. 1B is an enlarged cross-sectional view schematically illustrating details of bonding metals, a bonding layer and a passivation layer in the semiconductor die as shown in FIG. 1A, according to some embodiments of the present disclosure.

FIG. 2 is a schematic cross-sectional view illustrating an edge portion of a semiconductor package including the semiconductor die as described with reference to FIG. 1A, FIG. 1B and another semiconductor die bonded thereto, according to some embodiments of the present disclosure.

FIG. 3 is a flow diagram illustrating a process for forming the bonding metals, the bonding layer and the passivation layer in a device wafer to be singulated to form each of the semiconductor dies as shown in FIG. 2, according to some embodiments of the present disclosure.

FIG. 4A through FIG. 4G are schematic cross-sectional views illustrating intermediate structures at various stages during the process as shown in FIG. 3.

FIG. 5 is a flow diagram illustrating a process for forming a device wafer to be singulated to form a semiconductor die, according to some embodiments of the present disclosure.

FIG. 6A through FIG. 6F are schematic cross-sectional views illustrating structures at various stages during the process as shown in FIG. 5.

FIG. 7 is a flow diagram illustrating a process for forming the semiconductor package as shown in FIG. 2, according to some embodiments of the present disclosure.

FIG. 8A through FIG. 8K are schematic cross-sectional views illustrating structures at various stages during the process as shown in FIG. 7.

FIG. 9 is a schematic cross-sectional view illustrating a semiconductor die, according to some embodiments of the present disclosure.

FIG. 10 is a schematic cross-sectional view illustrating a semiconductor package including the semiconductor die as shown in FIG. 9, according to some embodiments of the present disclosure.

FIG. 11 is a schematic cross-sectional view illustrating a semiconductor die, according to some embodiments of the present disclosure.

FIG. 12 is a schematic cross-sectional view illustrating a semiconductor package including the semiconductor die as shown in FIG. 11, according to some embodiments of the present disclosure.

FIG. 13 is a schematic cross-sectional view illustrating a semiconductor die, according to some embodiments of the present disclosure.

FIG. 14 is a schematic cross-sectional view illustrating a semiconductor package including the semiconductor die as shown in FIG. 13, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The embodiments are intended to provide further explanations but are not used to limit the scope of the present disclosure.

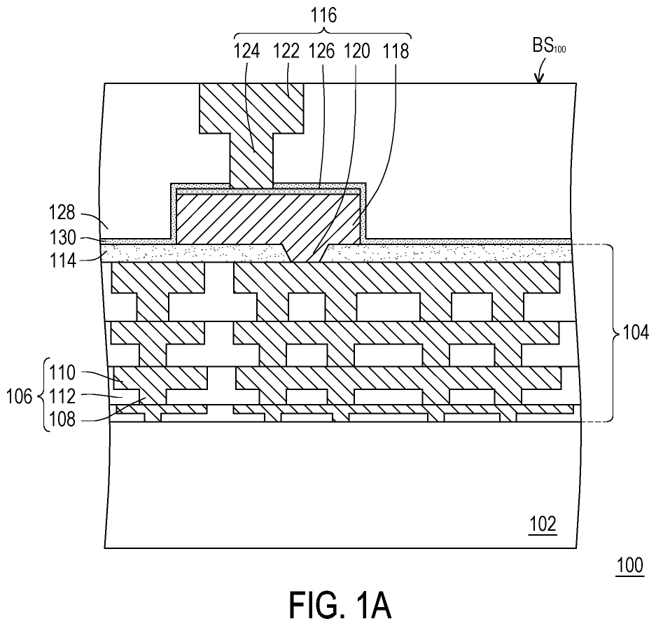

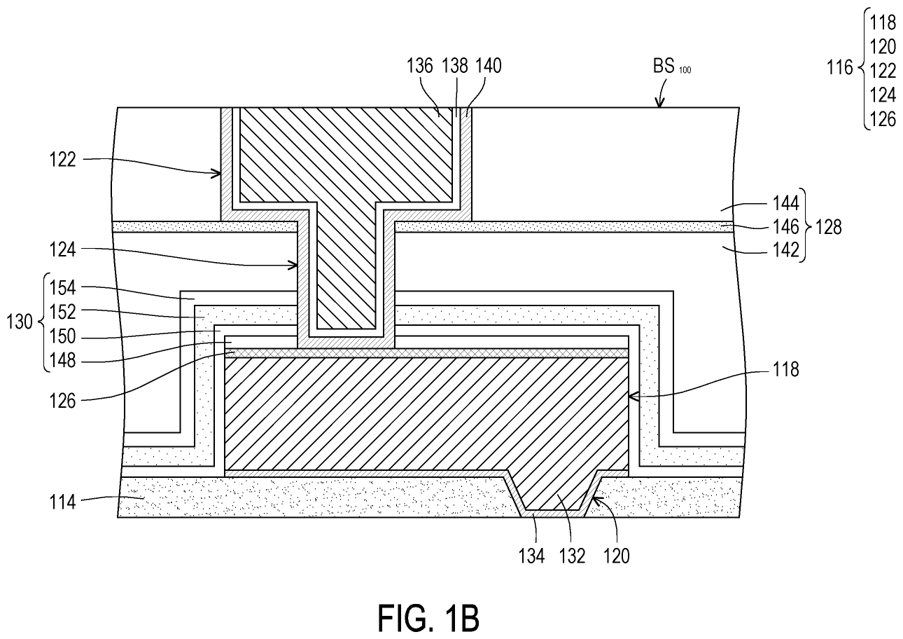

FIG. 1A is a schematic cross-sectional view illustrating a semiconductor die 100 included in a semiconductor package, according to some embodiments of the present disclosure.

Referring to FIG. 1A, the semiconductor die 100 includes a front-end-of-line (FEOL) structure 102. Although not shown, the FEOL structure 102 includes a semiconductor substrate and active devices formed on the semiconductor substrate. As an example, the active devices may include field effect transistors, and may be interconnected to form logic circuits and/or memory arrays. Further, the FEOL structure 102 may further include contacts plugs and local interconnecting lines for routing the active devices. The contact plugs may stand on terminals of the active devices, whereas the local interconnecting lines may extend over the contact plugs, and provide lateral routing paths.

A back-end-of-line (BEOL) structure 104 is formed on the FEOL structure 102. The BEOL structure 104 includes a stack of metallization layers 106. Each of the metallization layers 106 may include contact vias 108 and conductive wirings 110 functioned as intermediate and global interconnections of the active devices in the FEOL structure 102. The contact vias 108 provide vertical conduction paths, whereas the conductive wirings 110 provide lateral conduction paths. In addition, the contact vias 108 and the conductive wirings 110 in each metallization layer 106 may be formed in one or more dielectric layer(s) 112. According to some embodiments, the contact vias 108 and the conductive wirings 110 respectively include copper or copper alloy, while the dielectric layers 112 are respectively formed of a silicon oxide based material, such as undoped silicon glass (USG), phosphosilicate glass (PSG), borophosphosilicate glass (BPSG), fluorosilicate glass (FSG) or the like. Further, in some embodiments, bottommost one(s) of the metallization layers 106 may be formed with dimensions finer than dimensions of overlying ones of the metallization layers 106, respectively. For instance, these dimensions may include line width, line pitch, line thickness and the like. Although the BEOL structure 104 is illustrated as having four metallization layers 106, the BEOL structure 104 may actually include less than or more than four metallization layers 106.

In some embodiments, the BEOL structure 104 further includes a passivation layer 114 covering the topmost one of the metallization layers 106. The passivation layer 114 may be formed of an insulating material. As examples, the passivation layer 114 may be formed of a silicon oxide based material (e.g., USG, PSG, BPSG, FSG or the like), silicon nitride, silicon oxynitride or the like.

As inputs/outputs (I/Os) of the semiconductor die 100, bonding metals 116 are formed over the metallization layers 106, and the semiconductor die 100 may contact and communicate with another semiconductor die or a package component through the bonding metals 116. Separate groups of the bonding metals 116 are respectively in electrical connection with conductive elements in the metallization layers 106. For illustration purpose, only one of these groups is shown in FIG. 1A.

The bonding metals 116 in each group may include a conductive pad 118 electrically connected to conductive elements in the metallization layers 106 through a conductive via 120. In those embodiments where the BEOL structure 104 includes the passivation layer 114 covering the metallization layers 106, the conductive pad 118 may lie on the passivation layer 114, and the conductive via 120 may extend through the passivation layer 114 from a bottom end of the conductive pad 118 to the topmost one of the metallization layers 106. As will be further described, the conductive pad 118 and the conductive via 120 are portions of a conductive element, and such conductive element may include a conductive material and one or more barrier layer(s) underlining the conductive material.

In addition to the conductive pad 118 and the conductive via 120, the bonding metals 116 in each group also include a bonding pad 122 lying over the conductive pad 118 and a conductive via 124 extending between the bonding via 122 and the conductive pad 118. The bonding pad 122 may be exposed at a bonding surface BS₁₀₀ of the semiconductor die 100, and is configured to be in contact with another semiconductor die or a package component. According to some embodiments, a top surface of the bonding pad 122 is substantially coplanar with the bonding surface BS₁₀₀ of the semiconductor die 100. The conductive via 124 extends downwardly from a bottom end of the bonding pad 122, and is electrically connected with the conductive pad 118. As will be further described, the bonding pad 122 and the conductive via 124 may be portions of a conductive element, and such conductive element may include a conductive material and one or more barrier layers covering sidewalls and a bottom surface of the conductive material.

Moreover, the bonding metals 116 in each group further include a conductive capping layer 126 covering the conductive pad 118 and laterally extending in between the conductive pad 118 and the overlying conductive via 124. According to some embodiments, the conductive capping layer 126 is identical with the conductive pad 118 in terms of size (e.g., width and length) and footprint area, and sidewalls of the conductive capping layer 126 may be substantially coplanar with sidewalls of the conductive pad 118. The conductive capping layer 126 is configured to protect the conductive pad 118 from being etched during formation of the bonding pad 122 and the conductive via 124. If the conductive pad 118 was subjected to the possible etching, a top surface of the conductive pad 118 may be locally recessed and roughened, and a contact area between the conductive pad 118 and the conductive via 124 may be reduced. Consequently, contact resistance between the conductive pad 118 and the conductive via 124 may be undesirably increased. In other words, by further inserting the conductive capping layer 126 between the conductive pad 118 and the conductive via 124 for protecting the conductive pad 118, improved electrical contact between the conductive pad 118 and the conductive via 124 can be ensured. In order to protect the conductive pad 118 from etchants used in a possible dielectric etching during formation of the bonding pad 122 and the conductive via 124, a conductive material for forming the conductive capping layer 126 must have great resistance against the etchants. Further, the conductive material for forming the conductive capping layer 126 is preferred to have good conductivity, to avoid from significantly raising the contact resistance between the conductive pad 118 and the conductive via 124. According to some embodiments, the conductive capping layer 126 is formed of titanium, tantalum, tantalum nitride, titanium nitride or the like. Moreover, the conductive capping layer 126 should be thick enough to provide sufficient protection for the conductive pad 118, while not being too thick to result in apparent increase of the contact resistance between the conductive pad 118 and the conductive via 124. According to some embodiments, a thickness of the conductive capping layer 126 ranges from about 30 Å to about 1200 Å.

The bonding metals 116 are embedded in a bonding layer 128. A top surface of the bonding layer 128 may be substantially coplanar with the topmost surfaces of the bonding metals 116 (e.g., the top surfaces of the bonding pads 122), and may define the bonding surface BS₁₀₀ of the semiconductor die 100, along with the topmost surfaces of the bonding metals 116. In other words, the semiconductor die 100 may be bonded with another semiconductor die or a package component via the bonding metals 116 and the bonding layer 128. As the bonding metals 116 are embedded in the bonding layer 128, the bonding layer 128 may laterally surround the bonding pads 122 and the conductive vias 124 in the bonding metals 116, cover and laterally surround the conductive pads 118 and the conductive capping layers 126 in the bonding metals 116, and cover the BEOL structure 104. The bonding layer 128 is electrically insulated. In addition, as will be further described, the bonding layer 128 may have a stack of sub-layers.

According to some embodiments, a passivation layer 130 extends along a bottom surface of the bonding layer 128. In these embodiments, the conductive pads 118 and the conductive capping layers 126 of the bonding metals 116 as well as the BEOL structure 104 may be separated from the bonding layer 128 by the passivation layer 130. In addition, the passivation layer 130 may conformally cover a top surface of the BEOL structure 104, the sidewalls of the conductive pads 118 and the sidewalls as well as top surfaces of the conductive capping layers 126. The passivation layer 130 is electrically insulated. As will be further described, the passivation layer 130 may include multiple sub-layers.

FIG. 1B is an enlarged cross-sectional view schematically illustrating details of the bonding metals 116, the bonding layer 128 and the passivation layer 130 as shown in FIG. 1A, according to some embodiments of the present disclosure.

Referring to FIG. 1B, the conductive pad 118 and the conductive via 120 in each group of the bonding metals 116 may be portions of a conductive element. A lower portion of this conductive element extending vertically to reach the metallization layers 106 defines the conductive via 120, whereas an upper portion of this conductive element extends laterally and defines the conductive pad 118. In those embodiments where the BEOL structure 104 further includes the passivation layer 114, the lower portion of this conductive element penetrates through the passivation layer 114, whereas the upper portion of this conductive element lies on the passivation layer 114. According to some embodiments, this conductive element includes a conductive material 132 and a barrier layer 134 conformally lining along a bottom surface of the conductive material 132. The conductive via 118 is defined by a lower portion of the conductive material 132 and a portion of the barrier layer 134 laterally surrounding and underlining the lower portion of the conductive material 132. On the other hand, the conductive pad 118 is defined by an upper portion of the conductive material 132 and another portion of the barrier layer 134 lying below the upper portion of the conductive material 132. According to some embodiments, the conductive material 132 includes an aluminum based material, such as aluminum or aluminum-copper alloy. In addition, the barrier layer 134 is also formed of a conductive material. In some embodiments, the barrier layer 134 is formed of tantalum nitride. During formation of the bonding pad 122 and the conductive via 124, the conductive material 132 can be protected by the conductive capping layer 126 extending along a top surface of the conductive material 132 (i.e., the top surface of the conductive pad 118). Accordingly, the top surface of the conductive material 132 (i.e., the top surface of the conductive pad 118) can remain substantially flat during formation of the bonding pad 122 and the conductive via 124, and great electrical contact between the conductive pad 118 and the conductive via 124 can be promised.

Similarly, the bonding pad 122 and the conductive via 124 may be portions of a conductive element. A lower portion of this conductive element extending vertically to reach the conductive capping layer 126 defines the conductive via 124, whereas an upper portion of this conductive element extends laterally and defines the bonding pad 122. According to some embodiments, this conductive element includes a conductive material 136 and barrier layers 138, 140 laterally surrounding and underlining the conductive material 136. The barrier layer 138 may extend between the conductive material 136 and the barrier layer 140. A lower portion of the conductive material 136 standing on the conductive capping layer 126 and portions of the barrier layers 138, 140 laterally surrounding and underlining this lower portion of the conductive material 136 define the conductive via 124. On the other hand, an upper portion of the conductive material 136 laterally extending over the conductive capping layer 126 as well as portions of the barrier layers 138, 140 laterally surrounding and underlining the upper portion of the conductive material 136 define the bonding pad 122. A top surface of the conductive material 136 and top surfaces of the barrier layers 138, 140 define the top surface of the bonding pad 122, which is part of the bonding surface BS₁₀₀ of the semiconductor die 100. According to some embodiments, the conductive material 136 includes a metallic material different from a metallic material of the conductive material 132. In those embodiments where the conductive material 132 includes an aluminum based material, the conductive material 136 may include copper. In addition, in some embodiments, the barrier layer 138 is formed of tantalum, while the barrier layer 140 is formed of tantalum nitride.

As described with reference to FIG. 1A, the bonding layer 128 may include a stack of sub-layers. As shown in FIG. 1B, in some embodiments, the bonding layer 128 includes dielectric layers 142, 144 and an etching stop layer 146 extending in between the dielectric layers 142, 144. The dielectric layer 142 is formed on the passivation layer 130. The conductive pad 118 and the conductive capping layer 126 are covered and laterally surrounded by the dielectric layer 142. The etching stop layer 146 may extend along a top surface of the dielectric layer 142. The conductive via 124 may extend through the etching stop layer 146 and an upper portion of the dielectric layer 142, to establish contact with the conductive capping layer 126. In addition, a portion of the etching stop layer 146 may extend along a bottom surface of the bonding pad 122. Further, the dielectric layer 144 is disposed on the etching stop layer 146, and laterally surrounds the bonding pad 122. A top surface of the dielectric layer 144 may be substantially coplanar with the top surface of the bonding pad 122, and may define the bonding surface BS₁₀₀ of the semiconductor die 100, along with the top surface of the bonding pad 122. The dielectric layers 142, 144 and the etching stop layer 146 are respectively formed of an insulating material. In addition, the etching stop layer 146 may have sufficient etching selectivity with respect to the dielectric layers 142, 144, to prevent the dielectric layer 142 from being shaped during patterning of the dielectric layer 144. According to some embodiments, the dielectric layers 142, 144 are respectively formed of a silicon oxide based material, whereas the etching stop layer 146 may be formed of a silicon nitride based material.

Further, according to some embodiments, the sub-layers of the passivation layer 130 include an insulating capping layer 148 extending along a top surface of the conductive capping layer 126. The insulating capping layer 148 and the conductive capping layer 126 may be substantially identical in term of size, and sidewalls of the insulating capping layer 148 may be substantially coplanar with the sidewalls of the conductive capping layer 126 as well as the sidewalls of the conductive pads 118. Accordingly, the sidewalls of the conductive capping layer 126 and the sidewalls of the conductive pad 118 may not be covered by the insulating capping layer 148, and the conductive pad 118 as well as the conductive capping layer 126 may not be laterally surrounded by the insulating capping layer 148. As a difference from the conductive capping layer 126 on which the conductive via 124 lands, the insulating capping layer 148 is penetrated through by the conductive via 124. As another difference from the conductive capping layer 126, the insulating capping layer 148 is formed of an insulating material. In some embodiments, the insulating capping layer 148 is formed of silicon oxynitride.

In some embodiments, the sub-layers of the passivation layer 130 further include conformal insulating layers 150, 152, 154. The conformal insulating layers 150, 152, 154 conformally cover the BEOL structure 104 and the overlying conductive pad 118, conductive capping layer 126 and insulating capping layer 148, and extend along a bottom surface of the dielectric layer 142. The conductive via 124 extends through the conformal insulating layers 150, 152, 154 and the insulating capping layer 148, to land on the conductive capping layer 126. The conformal insulating layer 150 is separated from the dielectric layer 142 by the conformal insulating layers 152, 154, and the conformal insulating layer 152 extends in between the conformal insulating layers 150, 154. The conformal insulating layers 150, 152, 154 are respectively formed of an insulating material. According to some embodiments, the conformal insulating layer 150 is formed of silicon nitride, the conformal insulating layer 152 is formed of silicon oxide. Further, in some embodiments, the conformal insulating layer 154 is formed of a silicon oxide based material (e.g., USG, PSG, BPSG, FSG or the like), silicon nitride, silicon oxynitride or the like.

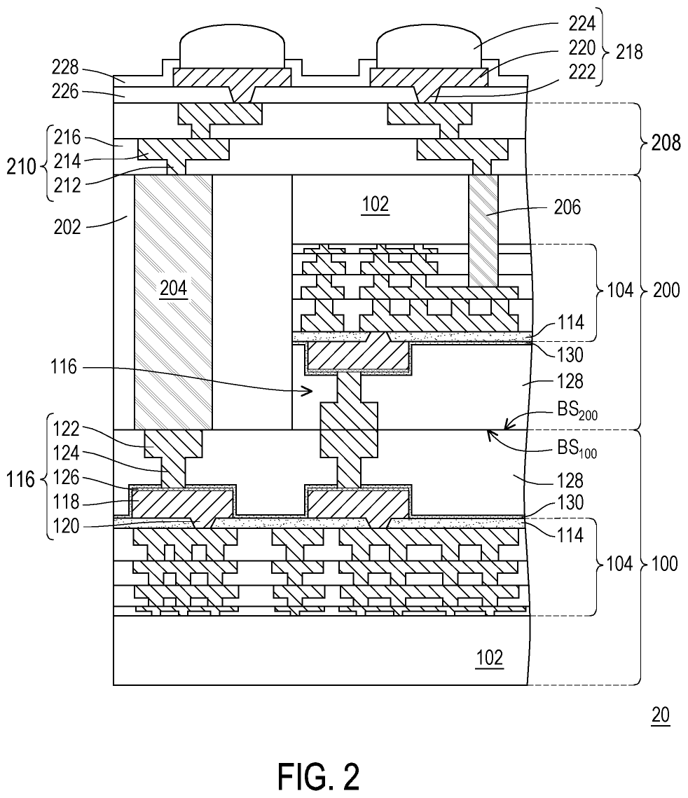

As described above, the semiconductor die 100 can be bonded with another semiconductor die or a package component via the bonding pad 122 and the bonding layer 128. FIG. 2 is a schematic cross-sectional view illustrating an edge portion of a semiconductor package including the semiconductor die 100 as described with reference to FIG. 1A, FIG. 1B and another semiconductor die 200 bonded with the semiconductor die 100, according to some embodiments of the present disclosure.

Referring to FIG. 2, more groups of the bonding metals 116 in the semiconductor die 100 are shown. Optionally, some groups of the bonding metals 116 are located in an edge portion of the semiconductor die 100. As similar to other groups of the bonding metals 116, the groups of the bonding metals 116 in the edge portion may be active bonding metals, which are electrically connected to the conductive elements in the metallization layers 106. Alternatively, the groups of the bonding metals 116 in the edge portion may be dummy bonding metals, which may not be electrically connected to the conductive elements in the metallization layers 106.

The semiconductor die 200 is structurally similar to the semiconductor die 100, and may be bonded to the semiconductor die 100 via a face-to-face manner. In other words, a bonding surface BS₂₀₀ defined by outermost surfaces of the bonding metals 116 and the bonding layer 128 in the semiconductor die 200 is in contact with the bonding surface BS₁₀₀ defined by outermost surfaces of the bonding metals 116 and the bonding layer 128 in the semiconductor die 100. Further, the bonding metals 116 in the semiconductor die 200 may be respectively bonded with one of the bonding metals 116 in the semiconductor die 100, while the bonding layer 128 in the semiconductor die 200 may be bonded with the bonding layer 128 in the semiconductor die 100. In some embodiments, the bonding pads 122 of the bonding metals 116 in the semiconductor die 200 are respectively bonded with one of the bonding pads 122 of the bonding metals 116 in the semiconductor die 100. In addition, as similar to the semiconductor die 100 shown in FIG. 1B, the bonding layer 128 of the semiconductor die 200 may also include two dielectric layers and an etching stop layer extending in between the dielectric layers. Further, the outermost dielectric layer of the bonding layer 128 in the semiconductor die 200 may be bonded with the outermost dielectric layer of the bonding layer 128 in the semiconductor die 100 (e.g., the dielectric layer 144 as shown in FIG. 1B).

As a difference from the semiconductor die 100, the semiconductor die 200 may be smaller in size as compared to the semiconductor die 100. According to some embodiments, a central portion of the semiconductor die 100 is overlapped and bonded with the semiconductor die 200, while a peripheral portion of the semiconductor die 100 laterally surrounding the central portion may not be overlapped with nor boned with the semiconductor die 200. In those embodiments where some groups of the bonding metals 116 in the semiconductor die 100 are located within the peripheral portion of the semiconductor die 100, these peripheral bonding metals 116 of the semiconductor die 100 may not be bonded with the bonding metals 116 of the semiconductor die 200.

In some embodiments, the semiconductor die 200 is laterally surrounded by a dielectric material 202. The dielectric material 202 is located on the peripheral portion of the semiconductor die 100, and in lateral contact with the semiconductor die 200. A top surface of the dielectric material 202 may be substantially coplanar with a back surface of the semiconductor die 200, which may be defined by a back surface of a semiconductor substrate in a FEOL structure 102 of the semiconductor die 200. In addition, an outer sidewall of the dielectric material 202 may be substantially coplanar with a sidewall of the semiconductor die 100. In some embodiments, the dielectric material 202 includes a silicon oxide based material, silicon nitride, silicon carbide, silicon oxynitride or the like.

In some embodiments, through dielectric vias 204 (only a single one is shown) are formed in the dielectric material 202. The through dielectric vias 204 extend through the dielectric material 202 along a vertical direction. In those embodiments where the semiconductor die 100 has some of the bonding metals 116 disposed within the peripheral portion of the semiconductor die 100, the through dielectric vias 204 may extend to top surfaces of these peripheral bonding metals 116, and establish electrical contact with these peripheral bonding metals 116. In alternative embodiments, the peripheral bonding metals 116 are absent, and the through dielectric vias 204 are not in electrical contact with any of the bonding metals 116. In other embodiments, the through dielectric vias 204 are omitted.

As another difference from the semiconductor die 100, the semiconductor die 200 may further include through substrate vias 206 (only a single one is shown). The through substrate vias 206 may extend into the BEOL structure 104 of the semiconductor die 200 from a back surface of the semiconductor die 200, which may be defined by a back surface of a semiconductor substrate in a FEOL structure 102 of the semiconductor die 200. The conductive elements in the BEOL structure 104 may be routed to a back side of the semiconductor die 200 along the through substrate vias 206. In alternative embodiments, the through substrate vias 206 are terminated in the FEOL structure 102 and are electrically connected to the conductive elements in the BEOL structure 104 by, for example, contact plugs.

Furthermore, a backside interconnection structure 208 is further disposed on the semiconductor die 200 and the dielectric material 202, for out routing the through dielectric vias 204 (if any) and the through substrate vias 206. As similar to the BEOL structure 104, the backside interconnection structure 208 may include a stack of metallization layers 210. Each of the metallization layers 210 may include contact vias 212 and conductive wirings 214. The contact vias 212 provide vertical routing paths, while the conductive wirings 214 provide lateral routing paths. In addition, the contact vias 212 and the conductive wirings 214 in each metallization layer 210 may be formed in one or more dielectric layer(s) 216. The contact vias 212 and the conductive wirings 214 are formed of a conductive material, and the dielectric layers 216 are formed of a dielectric material. According to some embodiments, the contact vias 212 and the conductive wirings 214 respectively include copper or copper alloy, while the dielectric layers 216 are respectively formed of a silicon oxide based material. Although the backside interconnection structure 208 is illustrated as having two metallization layers 210, the backside interconnection structure 208 may include more metallization layers 210.

Moreover, the semiconductor package 20 may further include backside metals 218. The backside metals 218 are electrically connected to the conductive elements in the backside interconnection structure 208, and may be functioned as inputs/outputs (I/Os) of the semiconductor package 20. According to some embodiments, the backside metals 218 include backside conductive pads 220 lying over the backside interconnection structure 208, and include backside conductive vias 222 connecting the backside conductive pads 220 to the backside interconnection structure 208. In addition, the backside metals 218 may further include electrical connectors 224 respectively disposed on one of the backside conductive pads 220. According to some embodiments, the electrical connectors 224 are conductive bumps, such as micro-bumps or controlled collapse chip connection (C4) bumps.

In some embodiments, the backside conductive pads 220 and the backside conductive vias 222 are covered and laterally surrounded by backside passivation layers 226, 228. The backside passivation layer 226 extends along a top surface of the backside interconnection structure 208, and laterally surrounds the backside conductive vias 222. The backside conductive pads 220 are disposed on the backside passivation layer 226, and are conformally covered by the backside passivation layer 228 formed on the backside passivation layer 226. In addition, the electrical connectors 224 penetrate through the backside passivation layer 228 to establish electrical contact with the backside conductive pads 220. As examples, the backside passivation layers 226, 228 may be formed of a silicon oxide based material, silicon nitride, silicon oxynitride or the like.

The semiconductor package 20 can be attached or mounted to another package component via the electrical connectors 224, and can be further processed to form a complete electronic component.

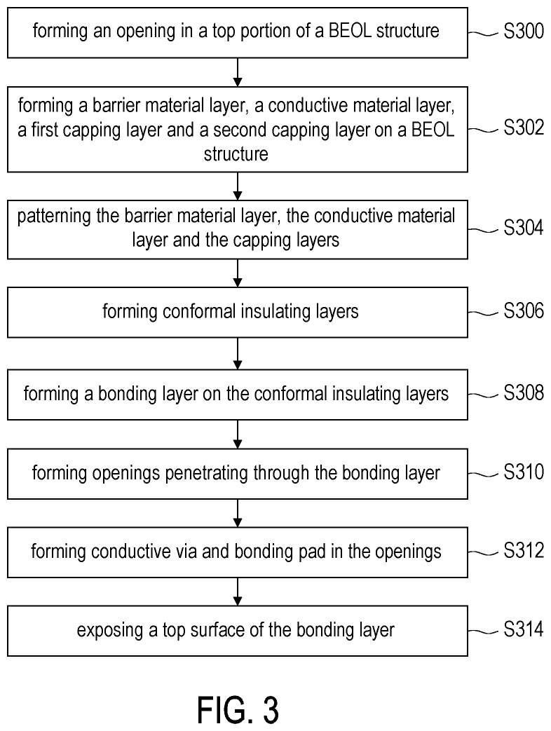

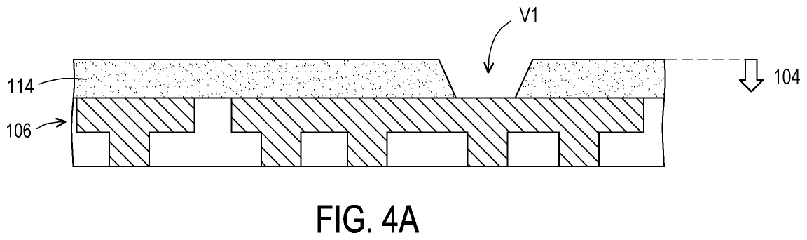

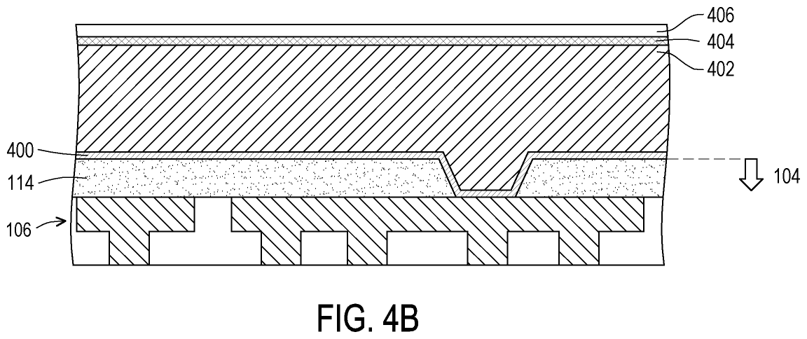

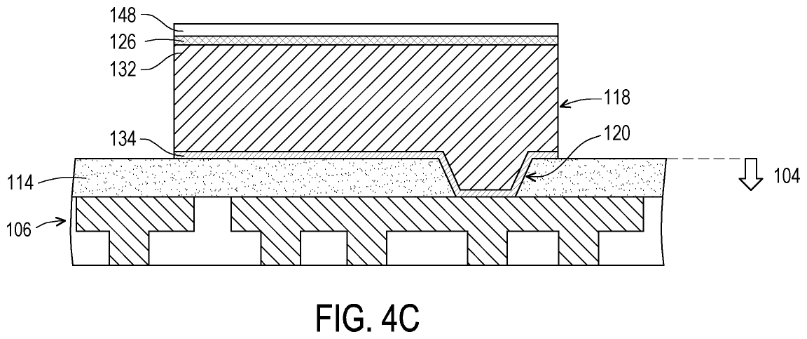

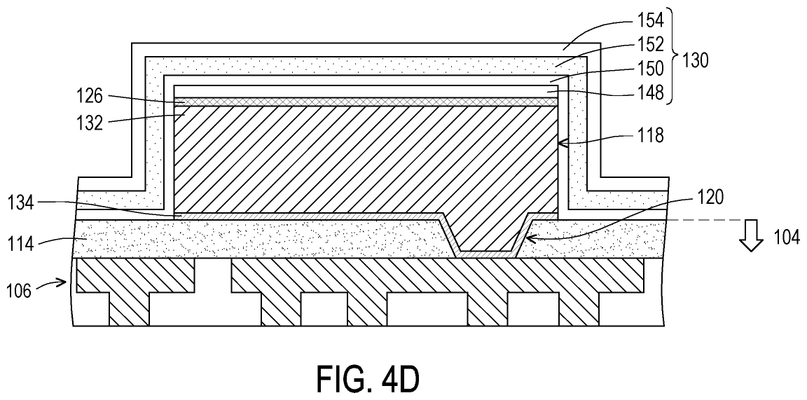

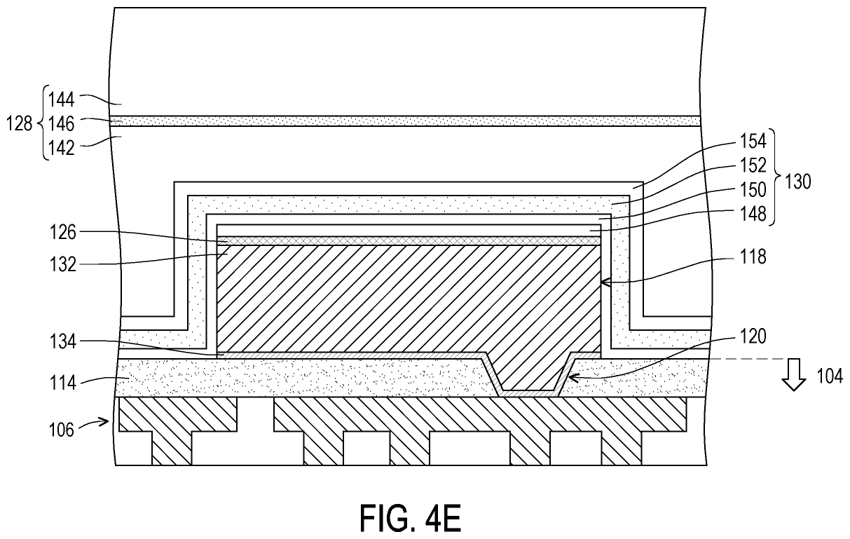

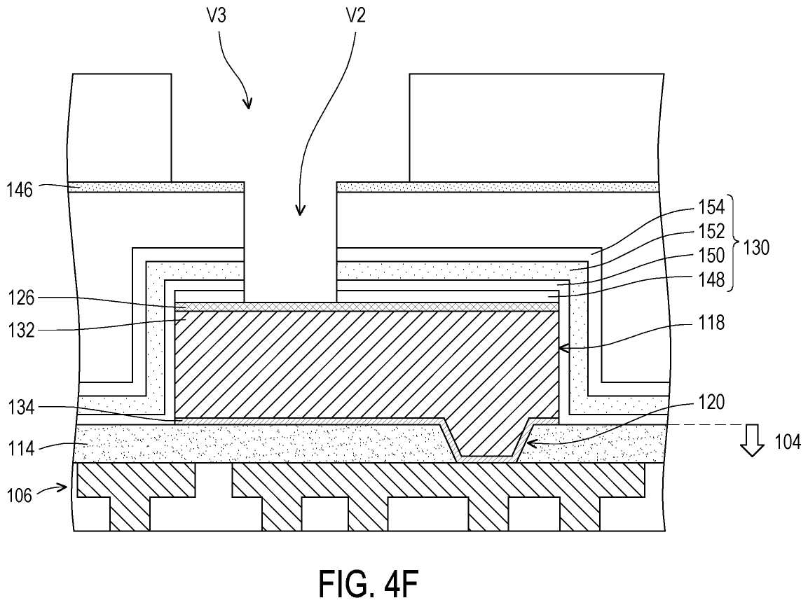

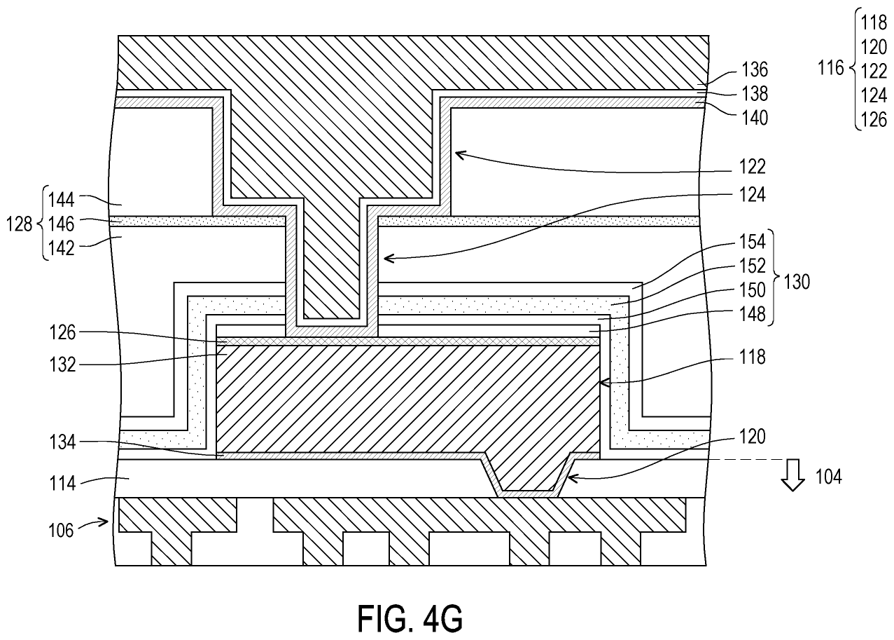

FIG. 3 is a flow diagram illustrating a process for forming the bonding metals 116, the bonding layer 128 and the passivation layer 130 in a device wafer to be singulated to form each of the semiconductor dies 100, 200, according to some embodiments of the present disclosure. FIG. 4A through FIG. 4G are schematic cross-sectional views illustrating intermediate structures at various stages during the process as shown in FIG. 3.

It should be noted that, for conciseness, only the topmost one of the metallization layers 106 in the BEOL structure 104 is shown in FIG. 4A through FIG. 4G, and the FEOL structure 102 is omitted from illustration. In addition, multiple groups of the bonding metals 116 should be formed in the process described with reference to FIG. 4A through FIG. 4G, despite that formation of only a single group of the bonding metals 116 is illustrated.

Referring to FIG. 3 and FIG. 4A, step S300 is performed, and an opening V1 is formed in a top portion of the BEOL structure 104, for accommodating the conductive via 120 to be formed in the following steps. In those embodiments where the BEOL structure 104 includes the passivation layer 114 lying on the metallization layers 106, the opening V1 penetrates through the passivation layer 114, to reach the topmost metallization layer 106. A lithography process and an etching process may be used for forming the opening V1.

Referring to FIG. 3 and FIG. 4B, step S302 is performed, and a barrier material layer 400, a conductive material layer 402 and capping layers 404, 406 are formed on the BEOL structure 104. The barrier material layer 400 to be patterned to form the barrier layer 134 as shown in FIG. 1B covers a top surface of the BOEL structure 104 (e.g., a top surface of the passivation layer 114, according to some embodiments), and conformally extends along surfaces defining the opening V1 in the passivation layer 114. The conductive material layer 402 to be patterned to form the conductive material 132 as shown in FIG. 1B is formed on the barrier material layer 400, and fills up the opening V1 in the passivation layer 114. The capping layers 404, 406 are stacked on the conductive material layer 402, and will be patterned to form the conductive capping layer 126 and the insulating capping layer 148 as shown in FIG. 1B, respectively. The barrier material layer 400, the conductive material layer 402 and the capping layers 404, 406 are respectively formed by a deposition process. In some embodiments, the barrier material layer 400, the conductive material layer 402 and the capping layer 404 are respectively formed by a physical deposition (PVD) process, whereas the capping layer 406 is formed by a CVD process.

Referring to FIG. 3 and FIG. 4C, step S304 is performed, and the barrier material layer 400, the conductive material layer 402 as well as the capping layers 404, 406 are patterned. The barrier material layer 400 is patterned to form the barrier layer 134 as shown in FIG. 1B. The conductive material layer 402 is patterned to form the conductive material 132 as shown in FIG. 1B. As described with reference to FIG. 1B, upper portions of the conductive material 132 and the barrier layer 134 laterally extending over the metallization layers 106 define the conductive pad 118, whereas lower portions of the conductive material 132 and the barrier layer 134 extending along a vertical direction to reach the topmost metallization layer 106 define the conductive via 120. In addition, the capping layer 404 is patterned to form the conductive capping layer 126 as shown in FIG. 1B, and the capping layer 406 is patterned to form the insulting capping layer 148 as shown in FIG. 1B. In some embodiments, a method for patterning the barrier material layer 400, the conductive material layer 402 and the capping layers 404, 406 includes a lithography process and at least one etching process.

Referring to FIG. 3 and FIG. 4D, step S306 is performed, and the conformal insulating layers 150, 152, 154 are formed. As such, the BEOL structure 104 and a stacking structure including the conductive pad 118, the conductive capping layer 126 and the insulating capping layer 148 are conformally covered, and the passivation layer 130 including the insulating capping layer 148 and the conformal insulating layers 150, 152, 154 is formed. In some embodiments, the conformal insulating layers 150, 152, 154 are respectively formed by a deposition process, such as a CVD process.

Referring to FIG. 3 and FIG. 4E, step S308 is performed, and the bonding layer 128 is formed on the conformal insulating layers 150, 152, 154. In those embodiments where the bonding layer 128 includes the dielectric layers 142, 144 and the etching stop layer 146, the dielectric layer 142, the etching stop layer 146 and the dielectric layer 144 are sequentially formed on the structure as shown in FIG. 4D. As an example, the dielectric layers 142, 144 and the etching stop layer 146 may be respectively formed by a deposition process, such as a CVD process.

Referring to FIG. 3 and FIG. 4F, step S310 is performed, and openings V2, V3 are formed through the bonding layer 128 and the passivation layer 130. The openings V2, V3 are configured to accommodate the conductive via 124 and the bonding pad 122 to be formed in the following step, respectively. In some embodiments, the opening V2 penetrates through the etching stop layer 146 and the dielectric layer 142 of the bonding layer 128, and further extends through the conformal insulating layers 150, 152, 156 and the insulating capping layer 148 of the passivation layer 130, until reaching a top surface of the conductive capping layer 126. On the other hand, the opening V3 may penetrate through the dielectric layer 144 of the bonding layer 128, and communicates with the opening V2. A lithography process and at least two etching processes may be used for forming the openings V2, V3. During these etching processes, the conductive pad 118 can be remained covered by the conductive capping layer 126 having a sufficient etching selectivity with respect to the bonding layer 128, thus can be prevented from being subjected to possible etching damages.

Referring to FIG. 3 and FIG. 4G, step S312 is performed, and the conductive via 124 as well as the bonding pad 122 are formed in the openings V2, V3. In those embodiments where the conductive via 124 and the bonding pad 122 are formed by the conductive material 136 and the barrier layers 138, 140 as shown in FIG. 1B, the barrier layers 140, 138 and the conductive material 136 are sequentially formed in the openings V2, V3. Currently, the barrier layers 140, 138 and the conductive material 136 may fill up the openings V2, V3, and may further extend on the bonding layer 128. According to some embodiments, the barrier layers 140, 138 are respectively formed by a deposition process (e.g., a CVD process or a PVD process), and the conductive material 136 is formed by a deposition process (e.g., a PVD process), a plating process or a combination thereof.

Thereafter, step S314 may be performed, to expose a top surface of the bonding layer 128, as shown in FIG. 1B. In those embodiments where the barrier layers 140, 138 and the conductive material 136 of the bonding pad 122 and the conductive via 124 previously covered the top surface of the bonding layer 128, a planarization process may be used for removing portions of the barrier layers 140, 138 and the conductive material 136 above the top surface of the bonding layer 128, so as to expose the top surface of the bonding layer 128. The exposed top surface of the bonding layer 128 could be a bonding surface BS₁₀₀/BS₂₀₀ of the semiconductor die 100/200. As examples, the planarization process may include a polishing process, an etching process or a combination thereof.

Up to here, the bonding metals 116, the bonding layer 128 and the passivation layer 130 have been formed in a device wafer. The device wafer can be singulated to form each of the semiconductor dies 100, 200 as described with reference to FIG. 2.

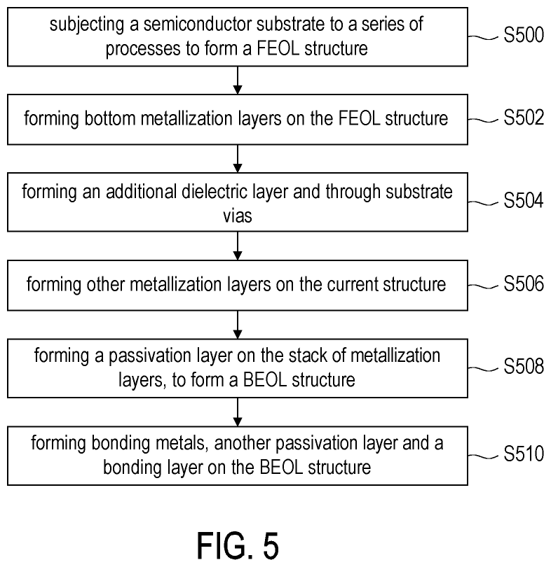

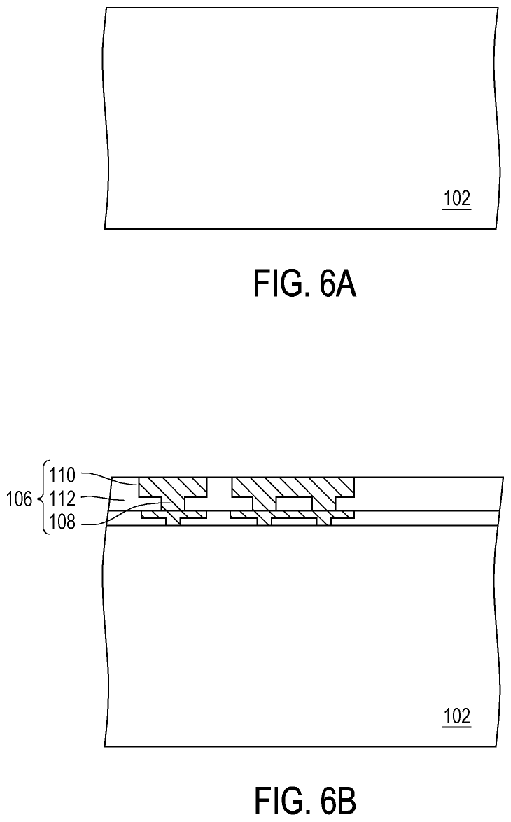

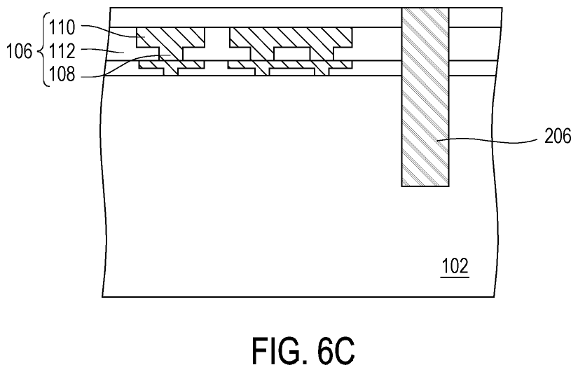

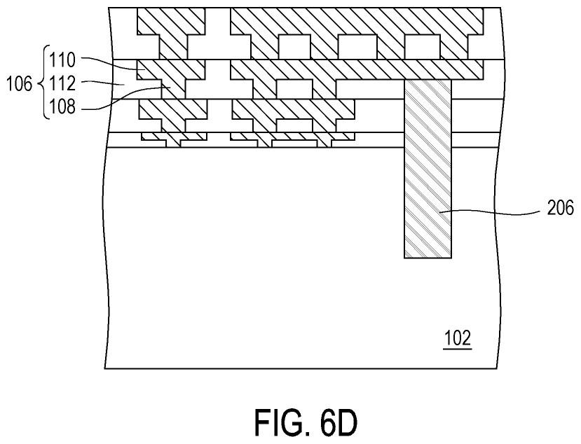

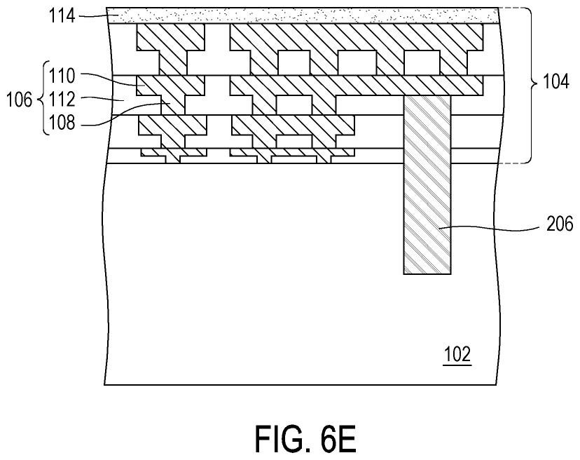

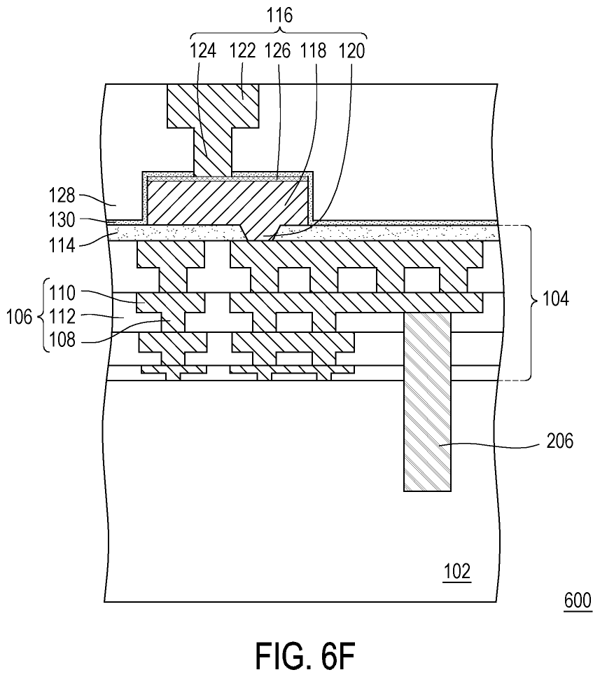

FIG. 5 is a flow diagram illustrating a process for forming a device wafer to be singulated to form the semiconductor die 200, according to some embodiments of the present disclosure. FIG. 6A through FIG. 6F are schematic cross-sectional views illustrating structures at various stages during the process as shown in FIG. 5.

Referring to FIG. 5 and FIG. 6A, step S500 is performed, and a semiconductor substrate is processed to form the FEOL structure 102. The semiconductor substrate as a base for the FEOL structure 102 will be further thinned after being singulated. In some embodiments, the semiconductor substrate has an embedded etching stop layer functioned as a stop layer during the thinning process. Various processes may be used for forming elements on the semiconductor substrate, to complete manufacturing of the FEOL structure 102. Those skilled in the art may choose suitable processes for forming the FEOL structure 102 according to process and design requirements, the present disclosure is not limited thereto.

Referring to FIG. 5 and FIG. 6B, step S502 is performed, and bottommost ones of the metallization layers 106 are formed on the FEOL structure 102. As described with reference to FIG. 1A, each metallization layer 106 may include one or more dielectric layer(s) 112 and conductive wirings 110 as well as contact vias 108 formed in the dielectric layer(s) 112. In some embodiments, damascene processes are used for forming these metallization layers 106.

Referring to FIG. 5 and FIG. 6C, step S504 is performed, and an additional dielectric layer 112 as well as the through substrate vias 206 (only a single one is shown) are formed. The additional dielectric layer 112 covers the previously formed metallization layers 106, and further process will be performed on this dielectric layer 112 to form a complete metallization layer 106. The through substrate vias 206 are formed into the FEOL structure 102 through the bottommost metallization layers 106 and the currently formed dielectric layer 112. During the current step, the through substrate vias 206 are terminated in the semiconductor substrate of the FEOL structure 102, and the embedded terminal surfaces of the through substrate vias 206 will be exposed when the semiconductor substrate is further thinned. In some embodiments, a method for forming the through substrate vias 206 includes forming deep via holes by a lithography process and at least one etching process. Subsequently, one or more conductive material(s) is/are filled into the deep via holes by deposition process(es), plating process(es) or combinations thereof. Further, portions of the conductive material(s) above the previously formed metallization layers 106 may be removed by a planarization process. Portions of the conductive material(s) remained in the deep via holes form the through substrate vias 206. As examples, the planarization process may include a polishing process, an etching process or a combination thereof.

Referring to FIG. 5 and FIG. 6D, step S506 is performed, and others of the metallization layers 106 are formed on the current structure. The through substrate vias 206 may be electrically connected to the conductive elements in the currently formed metallization layers 106 from below. In some embodiments, damascene processes are used for forming these metallization layers 106.

Referring to FIG. 5 and FIG. 6E, in some embodiments, step S508 is performed, and the passivation layer 114 is formed on the stack of metallization layers 106. Up to here, the BEOL structure 104 has been formed. In some embodiments, a method for forming the passivation layer 114 includes a deposition process, such as a CVD process.

Referring to FIG. 5 and FIG. 6F, step S510 is performed, and the bonding metals 116, the passivation layer 130 and the bonding layer 128 are formed on the BEOL structure 104. According to some embodiments, a method described with reference to FIG. 3, FIG. 4A through FIG. 4G and FIG. 1B is used for forming the bonding metals 116, the passivation layer 130 and the bonding layer 128.

So far, a device wafer 600 to be singulated to form the semiconductor die 200 has been formed. Similarly, in some embodiments, a device wafer to be singulated to form the semiconductor die 100 can be formed by this process, except that the step for forming the through substrate vias 206 may be omitted.

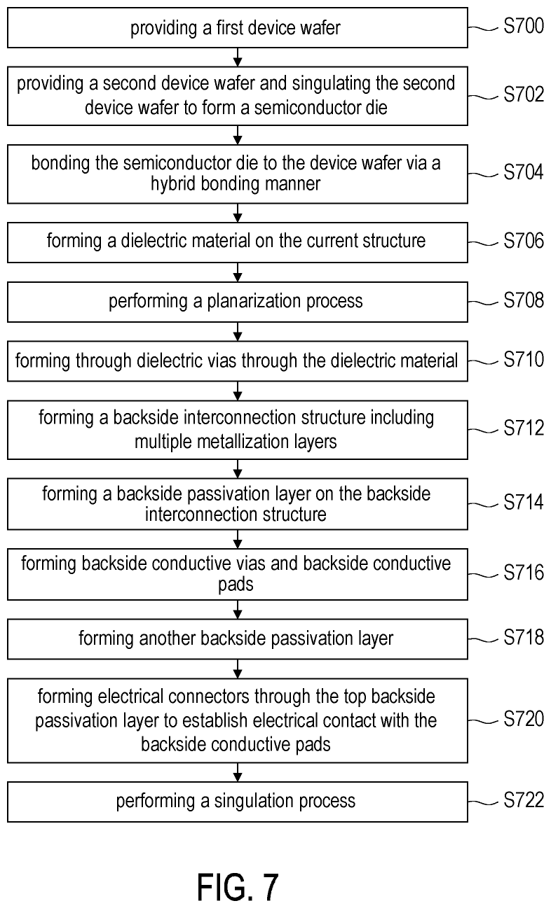

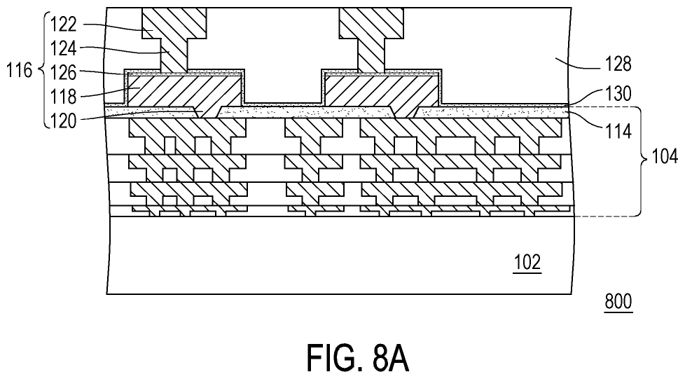

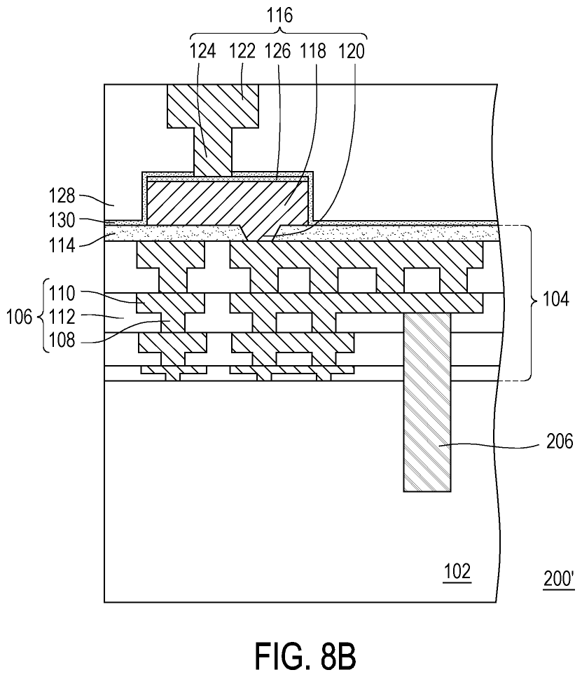

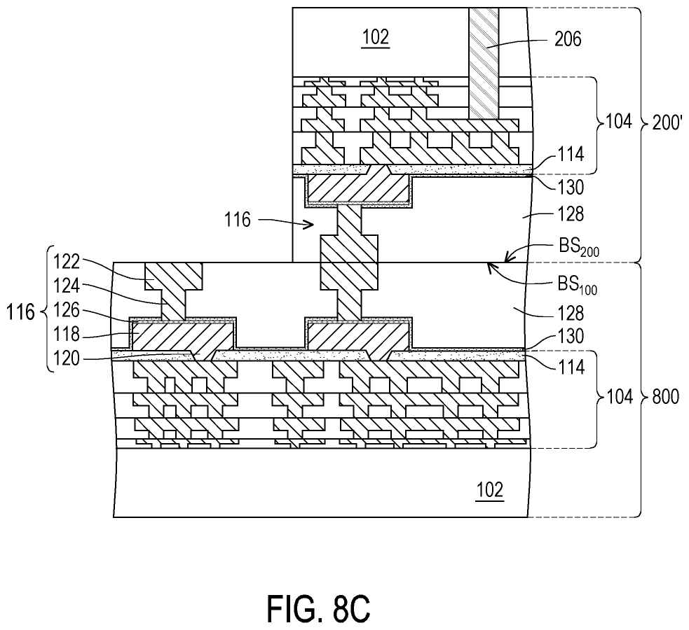

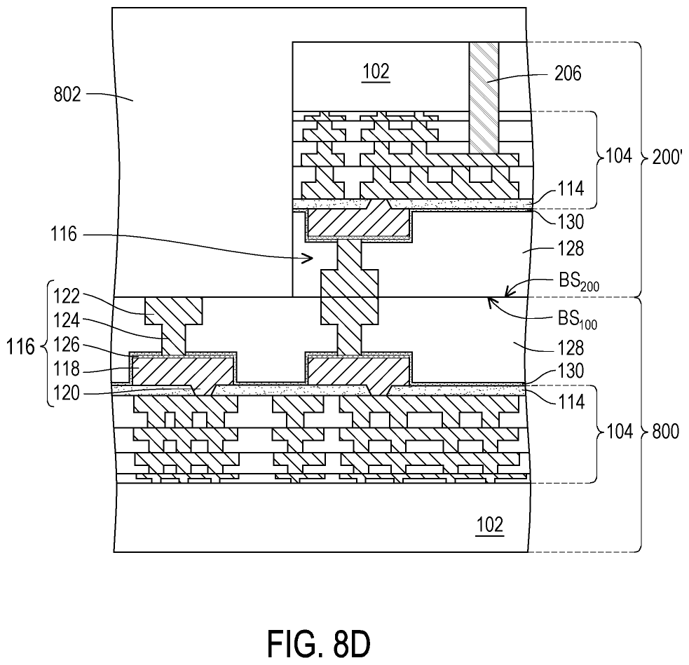

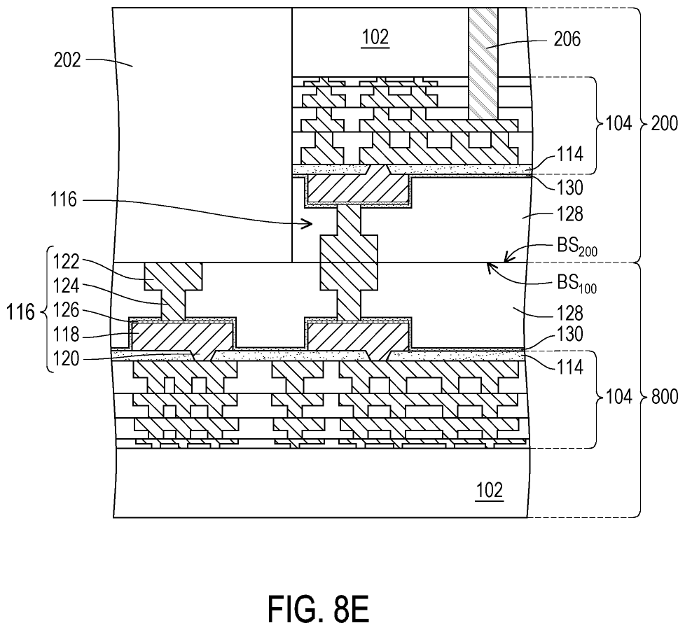

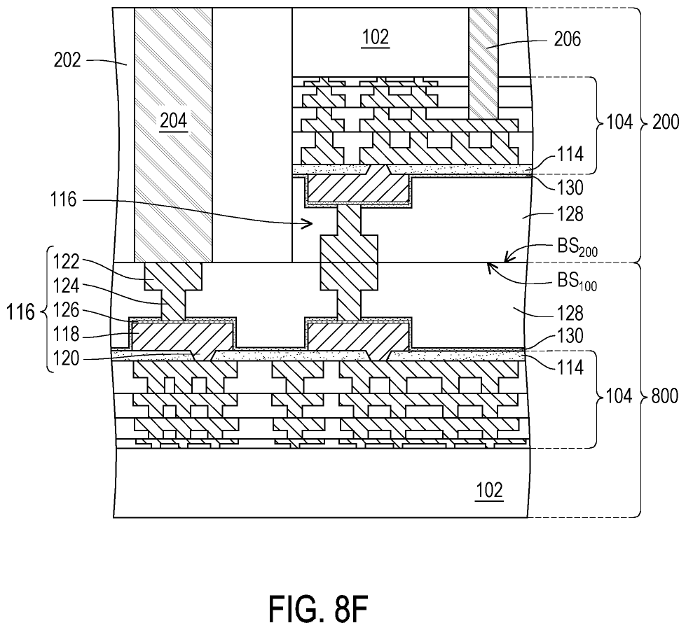

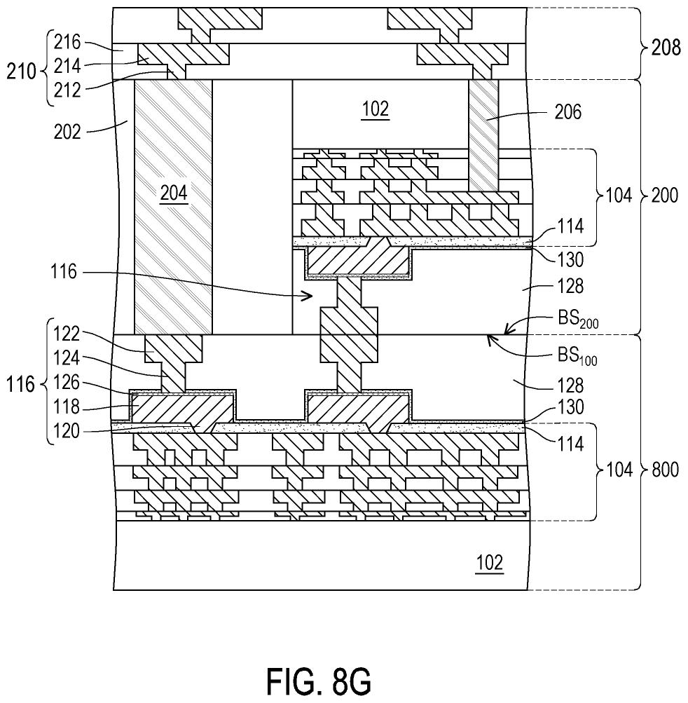

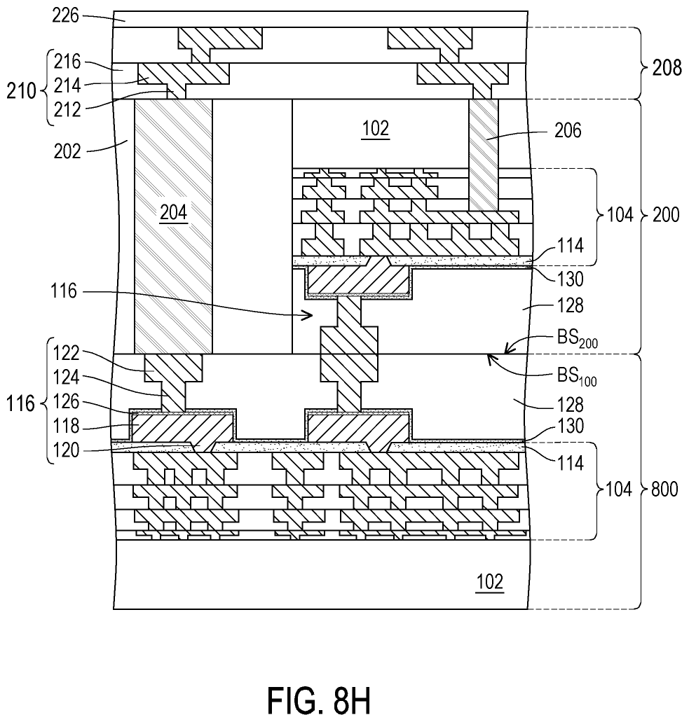

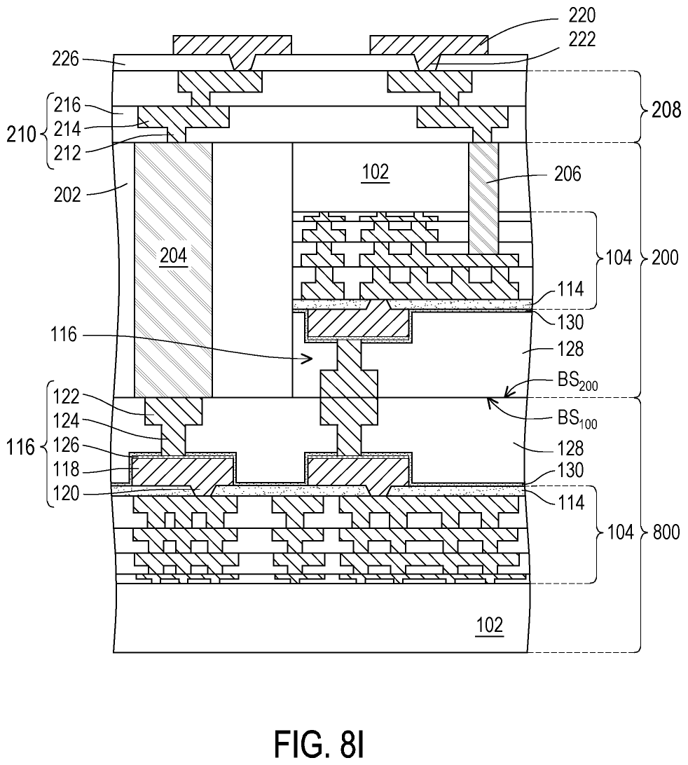

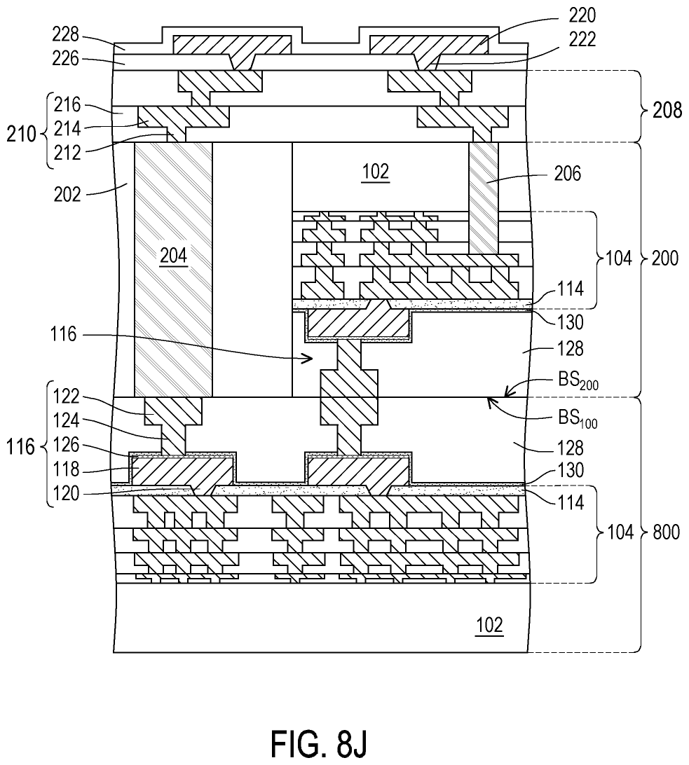

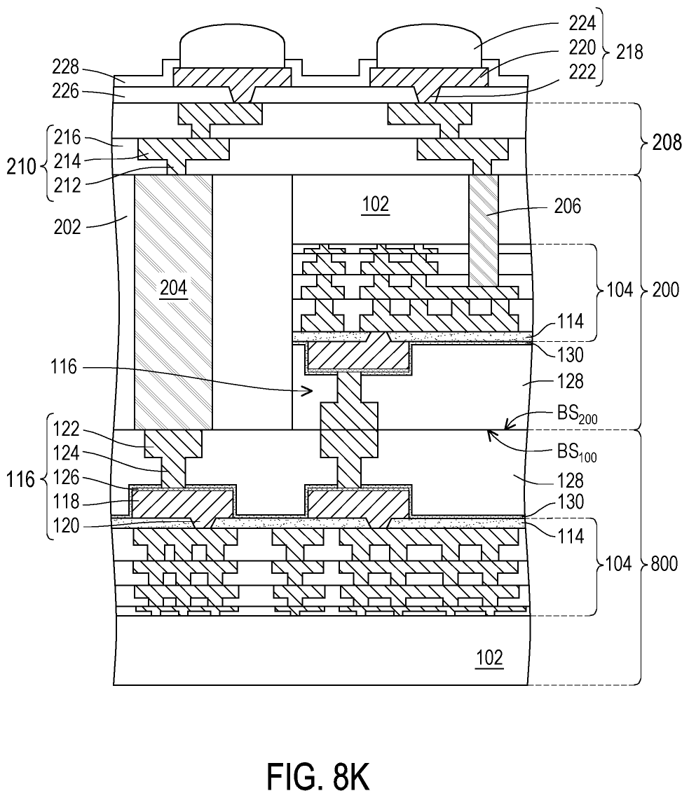

FIG. 7 is a flow diagram illustrating a process for forming the semiconductor package 20 as shown in FIG. 2, according to some embodiments of the present disclosure. FIG. 8A through FIG. 8K are schematic cross-sectional views illustrating structures at various stages during the process as shown in FIG. 7.

Referring to FIG. 7 and FIG. 8A, step S700 is performed, and a device wafer 800 to be singulated to form the semiconductor die 100 as shown in FIG. 2 is provided. As described above, in some embodiments, a process for preparing this device wafer 800 is similar to the process described with reference to FIG. 3, FIG. 4A through FIG. 4G and FIG. 1B, except that the step for forming the through substrate vias 206 may be omitted.

Referring to FIG. 7 and FIG. 8B, step S702 is performed, and the device wafer 600 as shown in FIG. 6F is provided and singulated to form a semiconductor die 200′. The semiconductor die 200′ will be thinned from a back surface of the semiconductor substrate in the FEOL structure 102 to form the semiconductor die 200 as shown in FIG. 2, and terminal surfaces of the through substrate vias 206 will be exposed. Currently, the terminal surfaces of the through substrate vias 206 remain buried in the semiconductor die 200′.

Referring to FIG. 7 and FIG. 8C, step S704 is performed, and the semiconductor die 200′ is bonded onto the device wafer 800 via a hybrid bonding manner. One or more heating treatment(s) is/are performed during the hybrid bonding. As a result of the heating treatment(s), the bonding pads 122 in the semiconductor die 200′ are respectively bonded to a bonding pad 122 in the device wafer 800, and the bonding layer of the semiconductor die 200′ is attached to the bonding layer 128 of the device wafer. As shown in FIG. 8C, the device wafer 800 may be partially bonded with the semiconductor die 200′. A portion of the device wafer 800 as the peripheral portion of the semiconductor die 100 may not be overlapped nor bonded with the semiconductor die 200′.

Referring to FIG. 7 and FIG. 8D, step S706 is performed, and a dielectric material 802 is formed on the current structure. The dielectric material 802 will be shaped to form the dielectric material 202 as shown in FIG. 2. Currently, the dielectric material 802 formed on the device wafer 800 laterally surrounds the semiconductor die 200′, and may further span over the semiconductor die 200′. In some embodiments, a method for forming the dielectric material 802 includes a deposition process, such as a CVD process.

Referring to FIG. 7 and FIG. 8E, step S708 is performed, and a planarization process is performed. During the planarization process, the dielectric material 802 is shaped to form the dielectric material 202, and the semiconductor die 200′ is thinned to form the semiconductor die 200. Currently, the terminal surfaces of the through substrate vias 206 are exposed. As examples, the planarization process may include a polishing process, an etching process or a combination thereof.

Referring to FIG. 7 and FIG. 8F, in some embodiments, step S710 is performed, and the through dielectric vias 204 (only a single one is shown) are formed through the dielectric material 202. A method for forming the through dielectric vias 204 may include forming through holes in the dielectric material 202 by a lithography process and an etching process. Subsequently, one or more conductive material(s) is/are filled into the through holes by deposition process(es), plating process(es) or combinations thereof. Further, portions of the conductive material(s) above the dielectric material 202 and the semiconductor die 200 may be removed by a planarization process. Portions of the conductive material(s) remained in the through holes form the through dielectric vias 204. As examples, the planarization process may include a polishing process, an etching process or a combination thereof.

Referring to FIG. 7 and FIG. 8G, step S712 is performed, and the backside interconnection structure 208 including multiple metallization layers 210 is formed on the dielectric material 202 and the semiconductor die 200. According to some embodiments, damascene processes are used for forming the metallization layers 210 in the backside interconnection structure 208.

Referring to FIG. 7 and FIG. 8H, step S714 is performed, and the backside passivation layer 226 is formed on the backside interconnection structure 208. According to some embodiments, a method for forming the backside passivation layer 226 includes a deposition process, such as a CVD process.

Referring to FIG. 7 and FIG. 8I, step S716 is performed, and the backside conductive vias 222 as well as the backside conductive pads 220 are formed. According to some embodiments, a method for forming the backside conductive vias 222 and the backside conductive pads 220 includes forming via holes in the backside passivation layer 226 by a lithography process and an etching process. Subsequently, a conductive material is provided on the backside passivation layer 226 by a deposition process (e.g., a PVD process). Portions of the conductive material filled in the via holes form the backside conductive vias 222. Further, portions of the conductive material over the backside passivation layer 226 is patterned by a lithography process and an etching process, to form the backside conductive pads 220.

Referring to FIG. 7 and FIG. 8J, step S718 is performed, and the backside passivation layer 228 is formed to cover the backside conductive pads 220 and the backside passivation layer 226. According to some embodiments, a method for forming the backside passivation layer 228 includes a deposition process, such as a CVD process.

Referring to FIG. 7 and FIG. 8K, step S720 is performed, and the electrical connectors 224 are formed through the backside passivation layer 228, to establish electrical contact with the backside conductive pads 220. A lithography process and an etching process may be used for etching through the backside passivation layer 228. In addition, those skilled in the art may use a suitable process for forming the electrical connectors 224, according to a selected type of the electrical connectors 224.

Thereafter, step S722 is performed, and a singulation process is performed. The device wafer 800 is singulated to form the semiconductor die 100. In addition, the dielectric material 202, the backside interconnection structure 208 and the backside passivation layers 226, 228 are also singulated along a sidewall of the semiconductor die 100. As a result, the semiconductor package as shown in FIG. 2 is obtained.

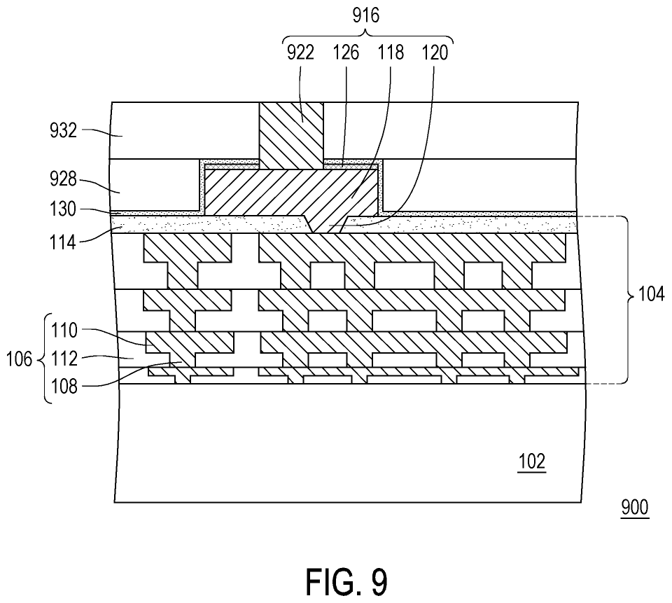

FIG. 9 is a schematic cross-sectional view illustrating a semiconductor die 900, according to some embodiments of the present disclosure.

Referring to FIG. 9, the semiconductor die 900 is similar to the semiconductor die 100 as described with reference to FIG. 1A and FIG. 1B. As a difference from the semiconductor die 100, bonding metals 916 of the semiconductor die 900 include conductive pillars 922 (only a single one is shown) as I/Os of the semiconductor die 900. The conductive pillars 922 penetrate through the passivation layer 130 to reach the conductive capping layers 126, and are separated from the conductive pads 118 from the conductive capping layers 126. As another difference from the semiconductor die 100, the semiconductor die 900 may further include a polymer layer 932 laterally surrounding the conductive pillars 922. Further, in the semiconductor die 900, a bonding layer 928 extends between the polymer layer 932 and the passivation layer 130. The polymer layer 932 is formed of a polymer material, such as polyimide. In addition, the bonding layer 928 may be a dielectric layer similar to one of the dielectric layers 142, 144 as described with reference to FIG. 1B, and may be formed of a silicon oxide based material.

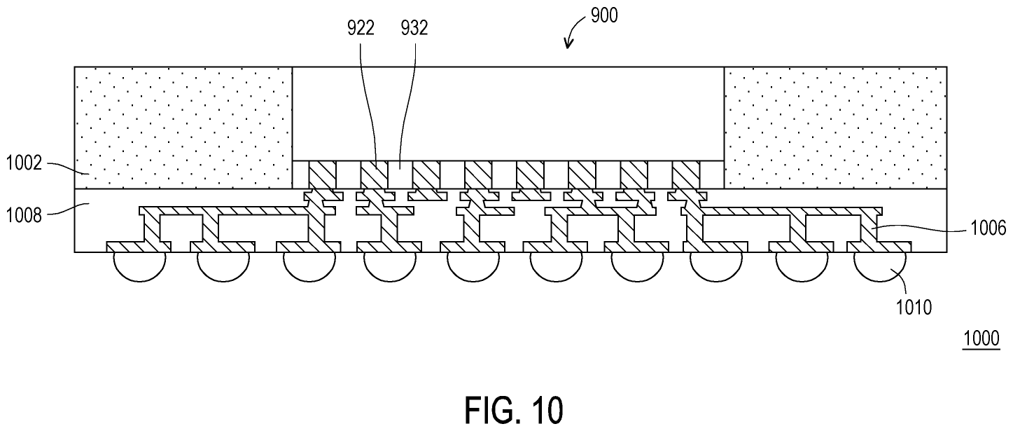

FIG. 10 is a schematic cross-sectional view illustrating a semiconductor package 1000 including the semiconductor die 900 as shown in FIG. 9, according to some embodiments of the present disclosure.

Referring to FIG. 10, the semiconductor die 900 is laterally encapsulated by an encapsulant 1002. In addition, a redistribution structure 1004 covers the semiconductor die 900 and the encapsulant 1002. Redistribution elements 1006 (e.g., conductive wires and vias) in a stack of polymer layers 1008 of the redistribution structure 1004 are electrically connected to the conductive pillars 922 of the semiconductor die 900, and rout the conductive pillars 922 to another side of the redistribution structure 1004 in a fan-out manner. Further, package I/Os 1010 are formed at the side of the redistribution structure 1004 facing away from the semiconductor die 900 and the encapsulant 1002. In some embodiments, the package I/Os 1010 are solder balls, C4 bumps, ball grid array (BGA) or the like.

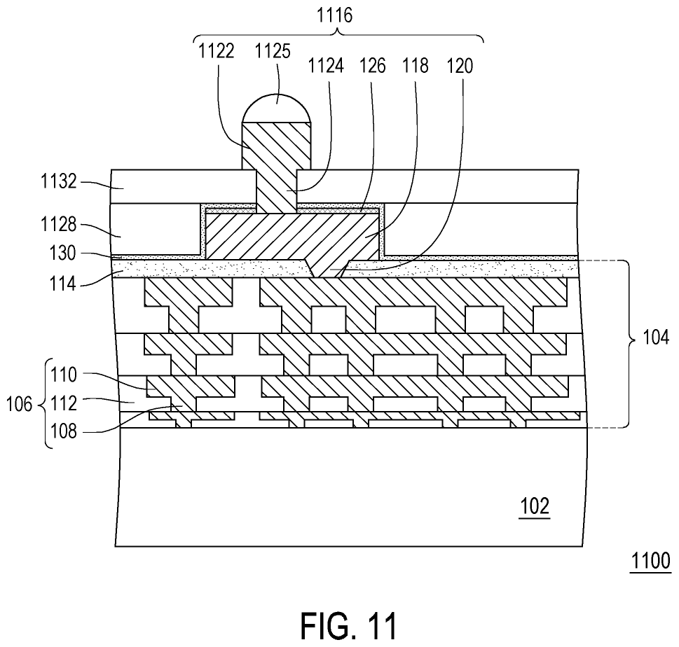

FIG. 11 is a schematic cross-sectional view illustrating a semiconductor die 1100, according to some embodiments of the present disclosure.

Referring to FIG. 11, the semiconductor die 1100 is similar to the semiconductor die 100 as described with reference to FIG. 1A and FIG. 1B. As a difference from the semiconductor die 100, bonding metals 1116 of the semiconductor die 1100 include conductive pillars 1122, conductive vias 1124 and solder caps 1125 (only a single one of the conductive pillars 1122, a single one of the conductive vias 1124 and a single one of the solder caps 1125 are shown). The conductive pillars 1122 are connected to the conductive capping layers 126 through the conductive vias 1124, and the conductive vias 1124 are separated from the conductive pads 118 by the conductive capping layers 126. Further, the conductive pillars 1122 are capped by the solder caps 1125. As another difference from the semiconductor die 100, the semiconductor die 1100 may further include a polymer layer 1132 laterally surrounding the conductive vias 1124. Further, in the semiconductor die 1100, a bonding layer 1128 extends between the polymer layer 1132 and the passivation layer 130. The polymer layer 1132 is formed of a polymer material, such as polyimide. In addition, the bonding layer 1128 may be a dielectric layer similar to one of the dielectric layers 142, 144 as described with reference to FIG. 1B, and may be formed of a silicon oxide based material.

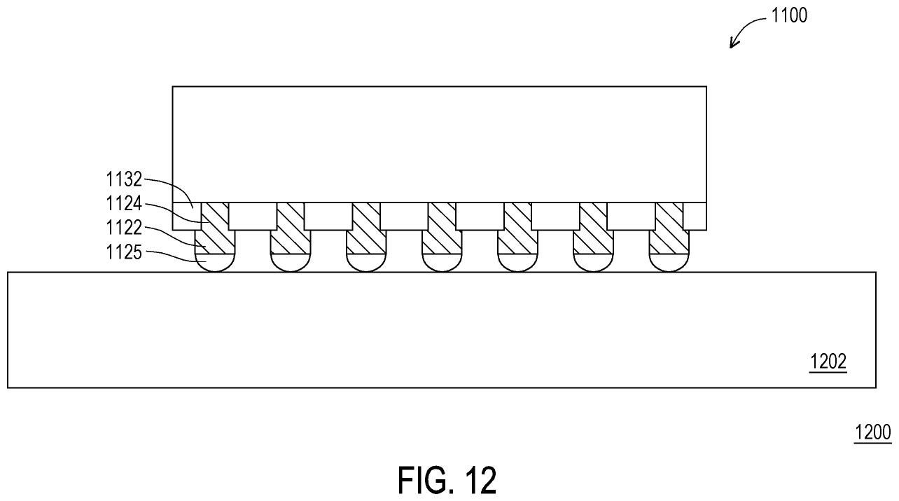

FIG. 12 is a schematic cross-sectional view illustrating a semiconductor package 1200 including the semiconductor die 1100 as shown in FIG. 11, according to some embodiments of the present disclosure.

Referring to FIG. 12, the semiconductor die 1100 are attached to a package component 1202 through the conductive pillars 1122 and the solder caps 1125 via a flip-chip bonding process. According to some embodiments, the package component 1202 is an interposer (e.g., a silicon interposer or an organic interposer), in which wirings (not shown) are disposed for routing the semiconductor die 1100 to another side of the interposer. Further, although not shown, the package component 1202 as the interposer may be further attached/mounted to a package substrate. Optionally, an underfill (not shown) is provided in a spacing between the semiconductor die 1100 and the package component 1202, and the conductive pillars 1122 as well as the solder caps 1125 are laterally surrounded by the underfill.

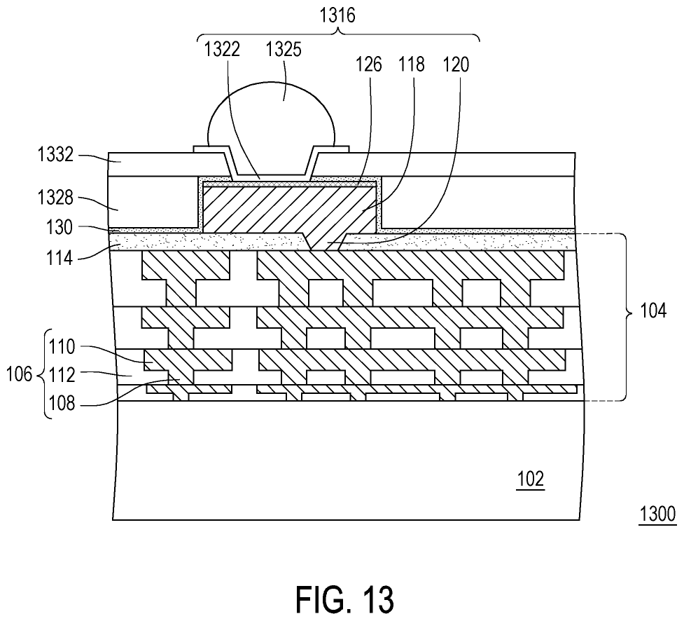

FIG. 13 is a schematic cross-sectional view illustrating a semiconductor die 1300, according to some embodiments of the present disclosure.

Referring to FIG. 13, the semiconductor die 1300 is similar to the semiconductor die 100 as described with reference to FIG. 1A and FIG. 1B. As a difference from the semiconductor die 100, bonding metals 1316 of the semiconductor die 1300 include bumps 1325 and under bump metallization patterns 1323 (only a single one bump 1325 and a single one under bump metallization pattern 1323 are shown). The bumps 1325 are connected to the conductive capping layers 126 through the under bump metallization patterns 1323, and the under bump metallization patterns 1323 are separated from the conductive pads 118 by the conductive capping layers 126. For instance, the bumps 1325 may be C4 bumps. As another difference from the semiconductor die 100, the semiconductor die 1300 may further include a polymer layer 1332 laterally surrounding lower portions of the under bump metallization patterns 1323 and the bumps 1325. Further, in the semiconductor die 1300, a bonding layer 1328 extends between the polymer layer 1332 and the passivation layer 130. The polymer layer 1332 is formed of a polymer material, such as polyimide. In addition, the bonding layer 1328 may be a dielectric layer similar to one of the dielectric layers 142, 144 as described with reference to FIG. 1B, and may be formed of a silicon oxide based material.

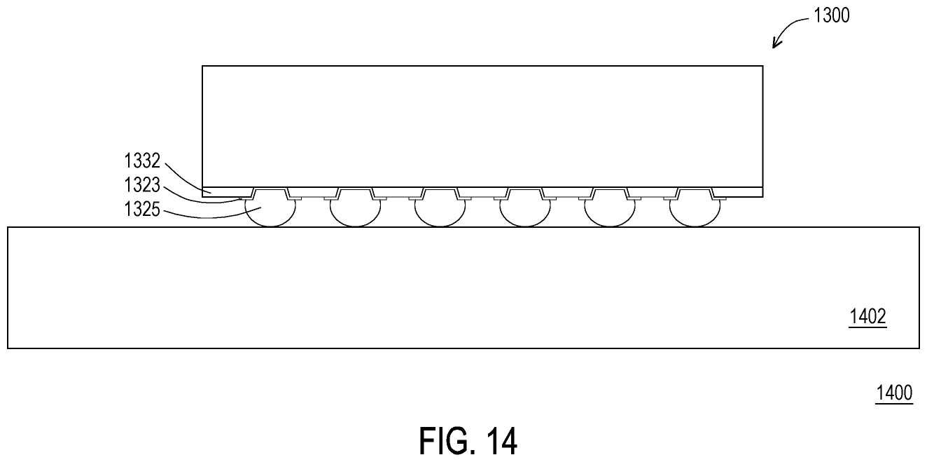

FIG. 14 is a schematic cross-sectional view illustrating a semiconductor package 1400 including the semiconductor die 1300 as shown in FIG. 13, according to some embodiments of the present disclosure.

Referring to FIG. 14, the semiconductor die 1300 are attached to a package component 1402 through the bumps 1325 via a flip-chip bonding manner. According to some embodiments, the package component is a package substrate. Optionally, an underfill (not shown) is provided in a spacing between the semiconductor die 1300 and the package component 1402, and the bumps 1325 are laterally surrounded by the underfill.

As above, a semiconductor die is designed to be bonded to another package component in a three-dimensional semiconductor package. Bonding metals in the semiconductor die include conductive pads (i.e., the conductive pads 118) and engaging features landing on the conductive pads (e.g., the bonding pads 122 and the conductive via 124 shown in FIG. 1A and FIG. 1B; the conductive pillars 922 as shown in FIG. 9; the conductive vias 1124, the conductive pillars 1122 and the solder caps 1125 as shown in FIG. 11; and the under bump metallization patterns 1323 and the bumps 1325 as shown in FIG. 13). Particularly, conductive capping layers (i.e., the conductive capping layers 126) are disposed between the conductive pads and the engaging features, for protecting the conductive pads. By disposing the conductive capping layers, the conductive pads can avoid from possible etching damages during formation of the engaging features, and may have substantially flat top surfaces. Advantageously, sufficient contact area between the conductive pads and the engaging features can be ensured, thus great contact resistance between the conductive pads and the engaging features can be promised.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a semiconductor die is provided. The semiconductor die comprises: a front-end-of-line (FEOL) structure, built on a semiconductor substrate, and comprising active devices; a back-end-of-line (BEOL) structure, formed on the FEOL structure, and comprising a stack of metallization layers; and bonding metals, disposed on the BEOL structure. The bonding metals comprise: a conductive pad, disposed over the BEOL structure, and electrically connected to the metallization layers in the BEOL structure; a conductive capping layer, lining along a top surface of the conductive pad; and an engaging feature, landing on the conductive capping layer and separated from the conductive pad by the conductive capping layer, wherein the semiconductor die is bonded to another semiconductor die or a package component by the engaging feature.

In another aspect of the present disclosure, a semiconductor package is provided. The semiconductor package comprises: a first semiconductor die and a second semiconductor die. Each semiconductor die comprises: a front-end-of-line (FEOL) structure, built on a semiconductor substrate; a back-end-of-line (BEOL) structure, formed on the FEOL structure, and comprising a stack of metallization layers; a conductive pad, disposed over the BEOL structure; a conductive capping layer, lining along a top surface of the conductive pad; an engaging feature, landing on the conductive capping layer and separated from the conductive pad by the conductive capping layer; and a bonding layer, laterally surrounding the conductive pad, the conductive capping layer, the conductive via and the bonding pad. The bonding pad of the first semiconductor die is bonded with the bonding pad of the second semiconductor die, and the bonding layer of the first semiconductor die is bonded with the bonding layer of the second semiconductor die.

In yet another aspect of the present disclosure, a method for manufacturing a semiconductor die is provided. The method comprises: forming a stack of metallization layers over a semiconductor substrate; forming a first conductive layer and a second conductive layer over the stack of metallization layers; simultaneously patterning the first and second conductive layers, wherein the first conductive layer is patterned to form a conductive pad, and the second conductive layer is patterned to form a conductive capping layer lining along a top surface of the conductive pad; forming a bonding layer to cover the conductive pad and the conductive capping layer; forming an opening through the bonding layer by at least one etching process, wherein the conductive capping layer prevents the conductive pad from being etched during the at least one etching process; and filling a conductive material in the opening to form an engaging feature configured to be bonded with another semiconductor die or a package component, wherein the engaging feature lands on the conductive capping layer, and is separated from the conductive pad by the conductive capping layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a front-end-of-line (FEOL) structure, built on a semiconductor substrate, and comprising active devices;
a back-end-of-line (BEOL) structure, formed on the FEOL structure, and comprising a stack of metallization layers; and
bonding metals, disposed on the BEOL structure, and comprising:
a conductive pad, disposed over the BEOL structure, and electrically connected to the metallization layers in the BEOL structure;
a conductive capping layer, lining along a top surface of the conductive pad; and
an engaging feature, landing on the conductive capping layer and separated from the conductive pad by the conductive capping layer, wherein the semiconductor die is bonded to another semiconductor die or a package component by the engaging feature.

2. The semiconductor die according to claim 1, wherein a sidewall of the conductive capping layer is substantially coplanar with a sidewall of the conductive pad.

3. The semiconductor die according to claim 1, wherein a footprint area of the conductive capping layer is substantially identical with a footprint area of the conductive pad.

4. The semiconductor die according to claim 1, wherein the engaging feature comprises:
a bonding pad, lying over the conductive capping layer, wherein a top surface of the bonding pad defines a portion of a bonding surface of the semiconductor die; and
a conductive via, connecting the bonding pad to the conductive capping layer along a vertical direction.

5. The semiconductor die according to claim 1, wherein the engaging feature comprises:
a conductive pillar, standing on the conductive capping layer, wherein a top surface of the conductive pillar defines a portion of a bonding surface of the semiconductor die.

6. The semiconductor die according to claim 1, wherein the engaging feature comprises:
a conductive pillar;
a solder cap, capping the conductive pillar; and
a conductive via, connecting the conductive pillar to the conductive capping layer along a vertical direction.

7. The semiconductor die according to claim 1, wherein the engaging feature comprises:
an under bump metallization pattern, lining along a top surface of the conductive capping layer; and
a bump, disposed on the under bump metallization pattern.

8. The semiconductor die according to claim 1, further comprising:
a passivation layer, conformally covering the BEOL structure and a stacking structure comprising the conductive pad and the conductive capping layer, wherein the engaging feature extends through the passivation layer to reach the conductive capping layer.

9. The semiconductor die according to claim 8, wherein the passivation layer is a multilayer structure, and comprises:
an insulating capping layer, lining along a top surface of the conductive capping layer; and
insulating layers, conformally covering the BEOL structure and a stacking structure comprising the conductive pad, the conductive capping layer and the insulating capping layer.

10. The semiconductor die according to claim 9, wherein a sidewall of the insulating capping layer is substantially coplanar with a sidewall of the conductive capping layer as well as a sidewall of the conductive pad.

11. The semiconductor die according to claim 1, further comprising a bonding layer, laterally surrounding the bonding metals.

12. The semiconductor die according to claim 11, wherein a top surface of the engaging feature is substantially coplanar with a top surface of the bonding layer, and the top surfaces of the engaging feature and the bonding layer collectively define a bonding surface of the semiconductor die.

13. The semiconductor die according to claim 12, wherein the bonding layer is a multilayer structure, and comprising:
a first dielectric layer, covering the conductive pad and the conductive capping layer, and laterally surrounding a lower portion of the engaging feature;
a second dielectric layer, laterally surrounding an upper portion of the engaging feature; and
an etching stop layer, sandwiched between the first and second dielectric layers.

14. The semiconductor die according to claim 11, further comprising a polymer layer lining along a top surface of the bonding layer.

15. A semiconductor package, comprising:
a first semiconductor die and a second semiconductor die, respectively comprising:
a front-end-of-line (FEOL) structure, built on a semiconductor substrate;
a back-end-of-line (BEOL) structure, formed on the FEOL structure, and comprising a stack of metallization layers;
a conductive pad, disposed over the BEOL structure;
a conductive capping layer, lining along a top surface of the conductive pad;
an engaging feature, landing on the conductive capping layer and separated from the conductive pad by the conductive capping layer; and
a bonding layer, laterally surrounding the conductive pad, the conductive capping layer, the conductive via and the bonding pad,
wherein the bonding pad of the first semiconductor die is bonded with the bonding pad of the second semiconductor die, and the bonding layer of the first semiconductor die is bonded with the bonding layer of the second semiconductor die.

16. The semiconductor package according to claim 15, further comprising a dielectric material formed on a peripheral portion of the first semiconductor die and laterally surrounding the second semiconductor die.

17. The semiconductor package according to claim 16, further comprising a through dielectric via penetrating through the dielectric material.

18. The semiconductor package according to claim 16, further comprising a backside interconnection structure disposed on the second semiconductor die and the dielectric material.

19. The semiconductor package according to claim 15, wherein the second semiconductor die further comprises a through substrate via extending into the FEOL structure from a back surface of the second semiconductor die facing away from the first semiconductor die.

20. A method for manufacturing a semiconductor die, comprising:
forming a stack of metallization layers over a semiconductor substrate;
forming a first conductive layer and a second conductive layer over the stack of metallization layers;
simultaneously patterning the first and second conductive layers, wherein the first conductive layer is patterned to form a conductive pad, and the second conductive layer is patterned to form a conductive capping layer lining along a top surface of the conductive pad;
forming a bonding layer to cover the conductive pad and the conductive capping layer;
forming an opening through the bonding layer by at least one etching process, wherein the conductive capping layer prevents the conductive pad from being etched during the at least one etching process; and
filling a conductive material in the opening to form an engaging feature configured to be bonded with another semiconductor die or a package component, wherein the engaging feature lands on the conductive capping layer, and is separated from the conductive pad by the conductive capping layer.
